(19) United States
(12) Patent Application Publication
(10) Pub. No.: US 2014/0212085 A1
(43) Pub. Date: Jul. 31, 2014

(54) OPTOCOUPLER

(71) Applicant: Georgios Margaritis, Los Alto, CA (US)

(72) Inventor: Georgios Margaritis, Los Alto, CA (US)

(21) Appl. No.: 13/752,392

(22) Filed: Jan. 29, 2013

(51) Int. Cl. G02B 6/12; H01L 23/00

(52) U.S. Cl. CPC G02B 6/12; H01L 24/11
USPC 385/14; 438/25

(57) ABSTRACT

A novel optocoupler is disclosed that includes at least one light emitting chip attached to one side of an optically transparent substrate and a photodetector chip attached to the opposite side of the optically transparent substrate. The light emitting chip receives electrical signals that are converted to light signals that are transmitted through the optically transparent substrate and are received and converted to electrical signals by the photodetector on the opposite side of the substrate. Further, a method to manufacture an optocoupler is disclosed where a light emitting chip is flip chip attached to one side of an optically transparent substrate with the light emitting surface of the chip facing the transparent substrate and a photodetector is flip chip attached to the opposite side of the optically transparent substrate, with the receiving surface of the chip facing the optically transparent substrate.

This application claims the benefit of U.S. Provisional Application No. 61/592,601, filed on Jan. 31, 2012.

### FIELD OF THE INVENTION

The present invention relates to the field of optocouplers used in electronic systems.

### BACKGROUND OF THE INVENTION

In many applications, it is important to transfer a signal from a first part of an electronic circuit to a second part with minimal electrical interaction between the two circuit parts. To achieve this goal, optocouplers are being used. In prior art, an optocoupler usually uses light emitting diodes (LEDs) to convert an electrical signal from the first part of the electronic circuit to an optical signal. A photodiode on the second part of the circuit converts the optical signal to an electrical signal. In this manner, the electrical signal is transfer with minimal electrical interaction between the two circuit parts. In prior art, light is transmitted from an LED to a photodiode through free space (air).

However, as circuit speed increases, LEDs can distort the signal. Further, the distance between the LED and photodiode needs to be minimized to achieve good quality reception by the photodiode. However, decreasing the distance between LED and photodiode will decrease the electrical isolation between the two circuit parts.

In this patent a novel optocoupler, and a method to make such optocoupler, is disclosed that can transmit high quality high-speed electrical signals between two parts of a circuit, with maximal electrical isolation between the two parts.

### SUMMARY OF THE INVENTION

A novel optocoupler is disclosed that includes at least one light emitting chip attached to one side of an optically transparent substrate and a photodetector chip attached to the opposite side of the optically transparent substrate. The light emitting chip receives electrical signals that are converted to light signals that are transmitted through the optically transparent substrate and are received and converted to electrical signals by the photodetector on the opposite side of the substrate. Further, a method to manufacture an optocoupler is disclosed where a light emitting chip is flip chip attached to one side of an optically transparent substrate with the light emitting surface of the chip facing the transparent substrate and a photodetector is flip chip attached to the opposite side of the optically transparent substrate, with the receiving surface of the chip facing the optically transparent substrate.

### LIST OF FIGURES

FIG. 1 shows a first embodiment of the optocoupler of the present invention.

FIG. 2 shows a second embodiment of the optocoupler of the present invention, using microvias through the substrate.

FIG. 3 shows a third embodiment of the optocoupler of the present invention, using wirebonds.

FIG. 4 shows a fourth embodiment of the optocoupler of the present invention, using microvias through the substrate.

FIG. 5 shows a perspective view of a portion of one embodiment of the present invention.

FIG. 6 shows a schematic representation of the optocoupler of the present invention.

FIG. 7 shows a fifth embodiment of the optocoupler of the present invention, using wirenbonds to connect the TIA and VCSEL driver to the substrate.

### DESCRIPTION OF THE INVENTION

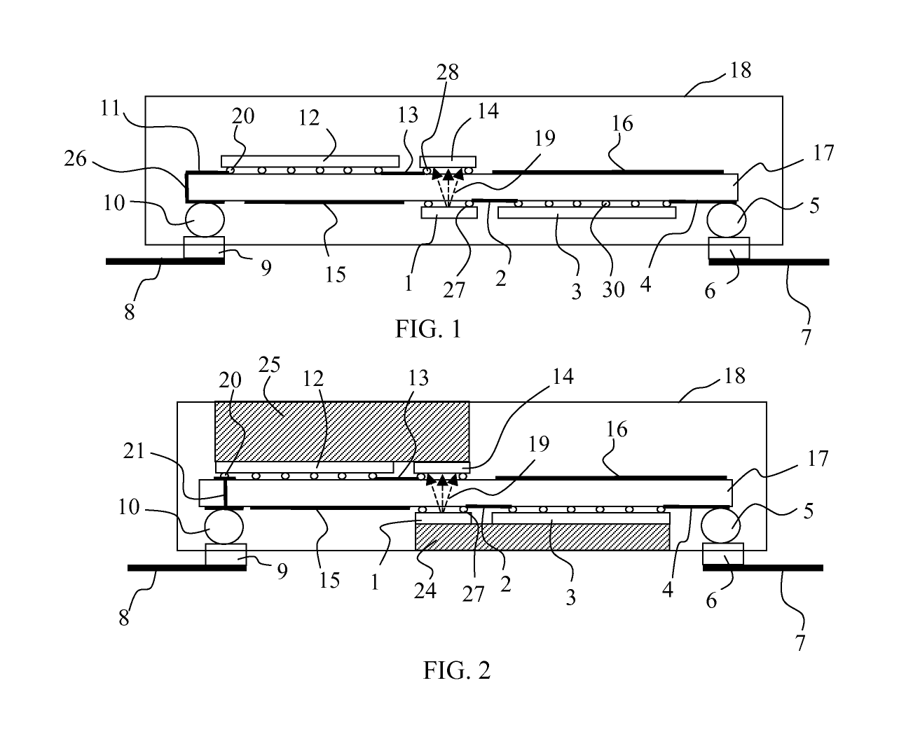

FIG. 1 shows a cross sectional view of one embodiment of the device of the present invention. It includes a light emitting chip 1, such as a vertical cavity surface emitting laser chip (a VCSEL laser chip, such as a 10 Gbit/s 850 nm Emcore VCSEL singlet laser) that is connected to a transmitting electronic circuit 3, such as a VCSEL driver (such as an Analog Devices ADN2530 differential VCSEL driver) through a controlled impedance (100 Ohm differential or 50-Ohm single ended) transmission line 2 that is deposited on an optically transparent to the VCSEL light substrate 17 (such as a Pyrex, fused silica, sapphire substrate etc.). The substrate thickness is 500 um, but can also be thinner or thicker. In general, the substrate should have a high refractive index, high dielectric constant, high dielectric strength and high thermal conductivity. In general, the substrate should have at least two flat opposite sides. The VCSEL laser 1 is flip-chip attached to the glass substrate 17 by means of solder joints 27. The light emitting surface of VCSEL laser 1 is facing the substrate 17. The VCSEL driver 3 is electrically connected to pins 6 of a package 18 (such as a Kyocera C-QFN package), by means of controlled impedance transmission lines 4 (e,g, 100 Ohm differential) deposited on the substrate 17 and solder joints 5. The VCSEL driver 3 is flip-chip attached to the glass substrate 17 by means of solder joints 30. The VCSEL laser is positioned such that its emitting surface faces the substrate. A photodiode chip 14 (such as an Enablence 10 Gbits/s PDCS70T-GS photodiode) is connected to a transimpedance amplifier (TIA) 12 (such as an Analog Devices ADN2820 TIA) through a controlled impedance (100 Ohm differential or 50 Ohm single-ended) transmission line 13 that is deposited on the substrate 17. The photodiode 14 is flip-chip attached to the glass substrate 17 by means of solder joints 28. The TIA 12 is electrically connected to pins 9 of the package 18, by means of controlled impedance transmission lines 11 (e,g, 100 Ohm differential) deposited on the substrate 17 and solder joints 10. The TIA 12 is flip-chip attached to the glass substrate 17 by means of solder joints 20. The photodiode 14 is positioned such that its receiving surface faces the substrate and is opposite to the emitting surface of the VCSEL laser 1 and can receive light signals emitted by the VCSEL laser. The lateral positional tolerance between photodiode and VCSEL is in the range of 20 um. Ground metalization planes 15 and 16 are deposited on the substrate 17 to provide better signal transmission. In general, the thickness and refractive index of the substrate should be such that sufficient light power emitted by the VCSEL is received by the photodiode.

FIG. 2 shows a second embodiment of the present invention. Metalized micro-vias 21 are formed in the substrate to electrically connect the TIA 12 to the solder joint 10. Further, heat sinks 24 and 25 formed from a block of solid metal, such as copper, are attached to the VCSEL driver 3 and VCSEL 1 and photodiode 14 and TIA 12 respectively, to increase heat transfer between these components and the package.

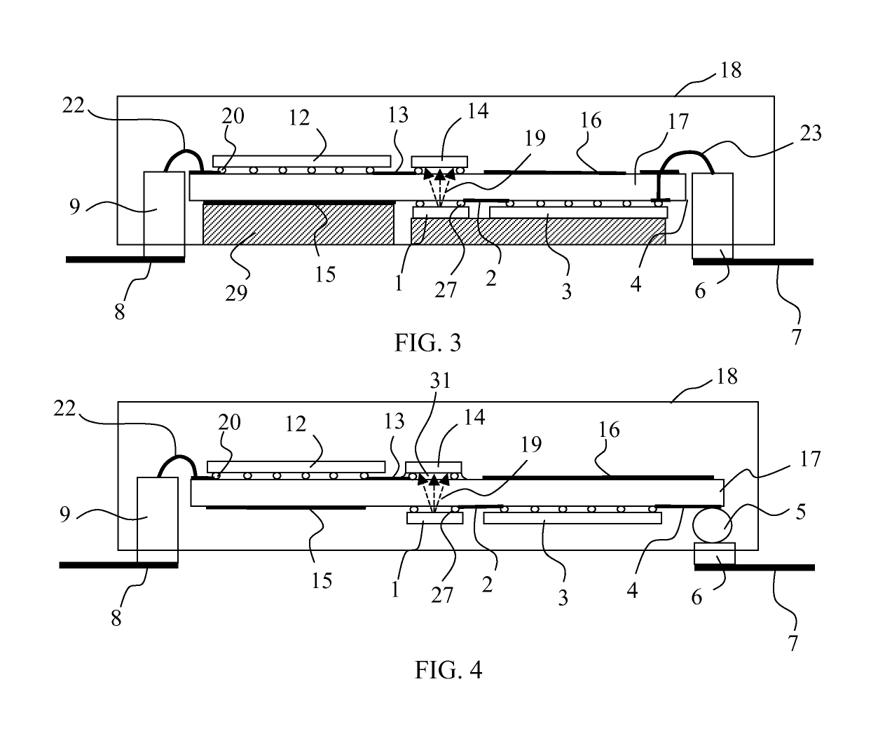

FIG. 3 shows a third embodiment of the present invention. Wirebonds 22 are used to electrically connect the TIA 12 to the package pins 9. Also, metalized micro-vias and wirebonds 23 are used to connect the VCSEL driver 3 to the package pins 6. Further heat can be transferred from the TIA 12 and photodiode 14 to the package 18, though the substrate 17 and heat sink 29, formed from a block of metal.

FIG. 4 shows a fourth embodiment of the present invention. Wirebonds 22 are used to electrically connect the TIA 12 to the package pins 9. The VCSEL driver 3 is electrically connected to pins 6 of the package 18, by means of the controlled impedance transmission line 4 deposited on the substrate 17 and the solder joints 5.

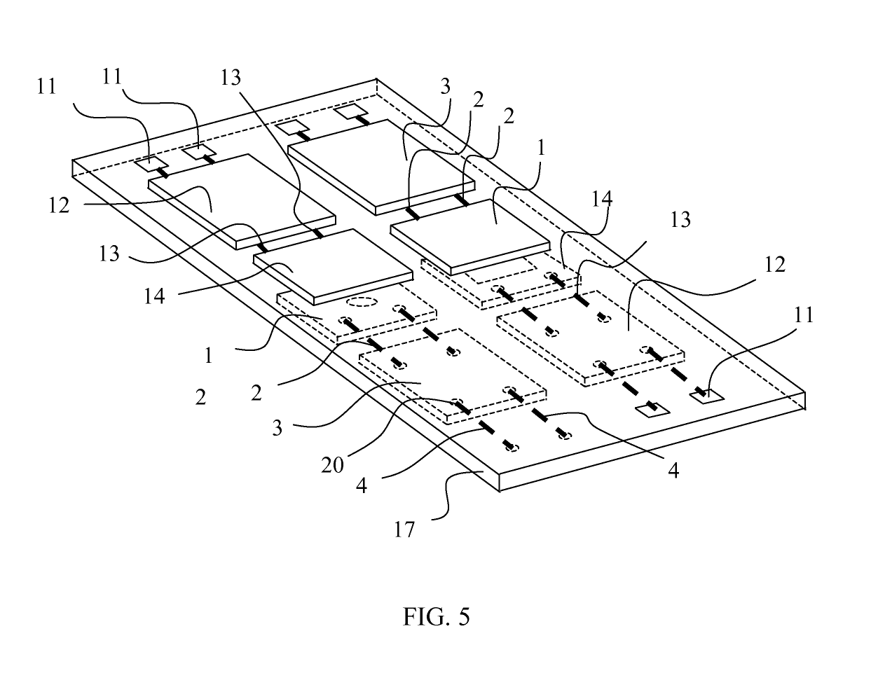

FIG. 5 shows another embodiment for a two-channel optocoupler where a second optocoupler is assembled in a parallel position on the same substrate as a first optocoupler. In general, multiple optocouplers can be positioned one net to another on the substrate. Also, VCSEL arrays (such as those by Emcore), photodiode arrays (such as those by Emcore), single chip multi-VCSEL driver (such as those from Iptronics) and single chip multi-TIA's (such as those by Iptronics) can be used instead of the single channel VCSEL chip 1 and/or the VCSEL driver 3 and/or the photodiode 14 and/or the TIA 12.

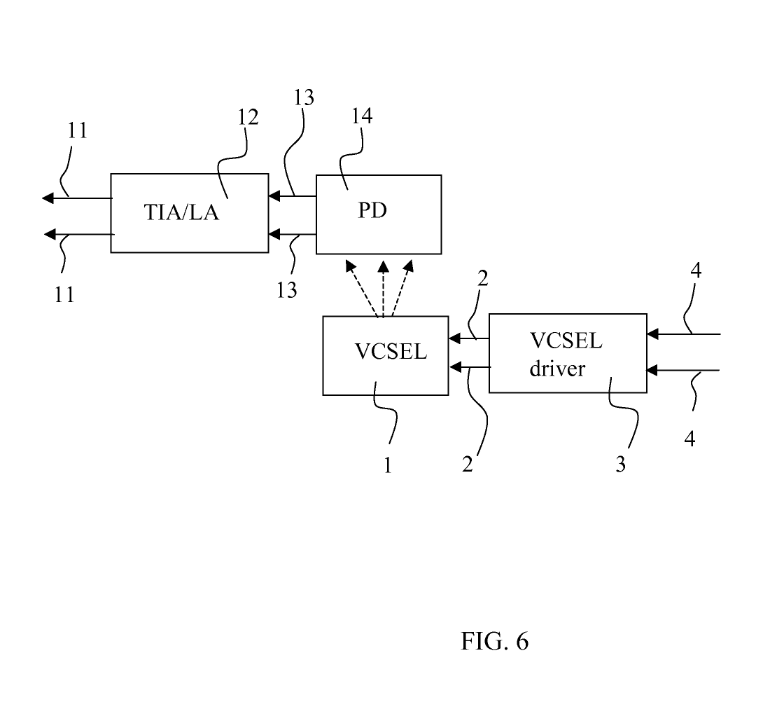

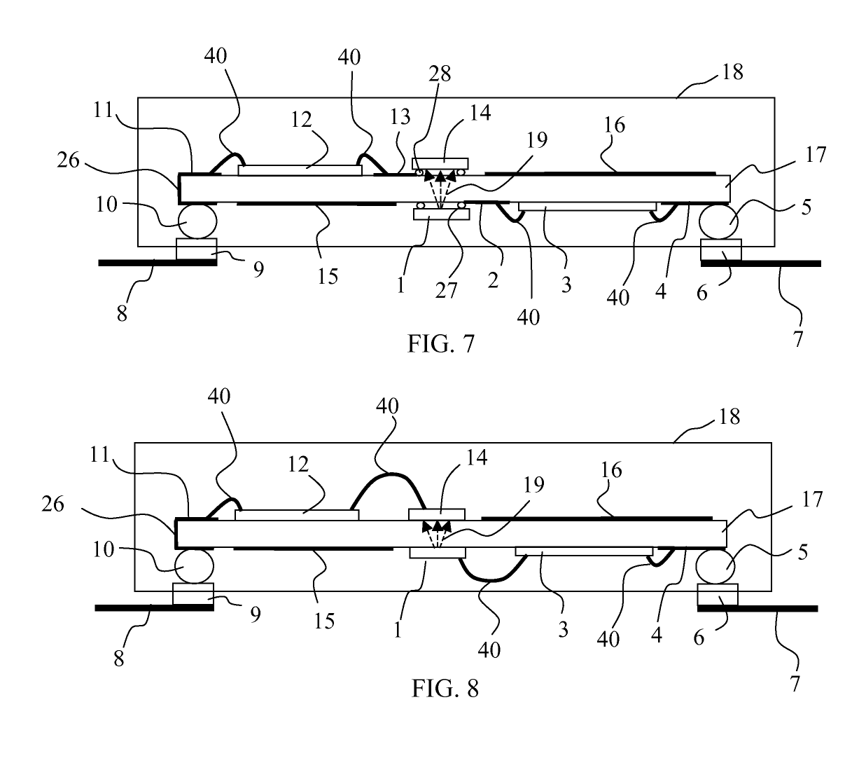

FIG. 6 is a schematic representation of the optocoupler of the present invention. A differential signal is input through the differential transmission line 4 into the VCSEL driver 3. The VCSEL driver 3 drives the VCSEL 1 to transmit light. The light hits the photodetector 14 that converts it to current. The photodetector current is converted to voltage through a TIA 12. The TIA outputs a differential signal into a differential transmission line 11. Preferably the input and output signals will be CML 100 Ohm differential, AC coupled, although other signaling formats such as PECL or LVDS could be used.

FIG. 7 is another embodiment of the present invention where pads on the top surface of the VCSEL driver 3 and the TIA 12 are attached to metal traces 2, 4, 11 and 13 with wirebonds 40, instead of solder bumps.

FIG. 8 is another embodiment of the present invention where pads on the back surface of the VCSEL 1 and photodiode 12 are wirebonded to the VCSEL driver 3 and to TIA 14 by wirebonds 40. It is noted that the emitting surface of the VCSEL 1 and the receiving surface of the photodiode 14 still face the substrate.

Numerous other embodiments of the present invention are possible:

The VCSEL chip 1 and/or the VCSEL driver 3 and/or the photodiode 14 and/or the TIA 12 could be solder bumped for flip attach with various solder alloys, such as tin-lead, tin-silver, tin-silver-copper, tin-silver-antimony, zinc and zinc alloys, bismuth and bismuth alloys, indium and indium alloys, gold-tin, and gold based alloys. Also, underfill 31 (shown under photodiode 14 in FIG. 4) could be disposed under the VCSEL 1, VCSEL driver 3, photodiode 14 and TIA 12, in the gap between any or all of these chips and the substrate.

Also, electrically conductive epoxy could be used instead of solder bumps for attaching the photodiode 14 or TIA 12 to the substrate 17.

Also, the VCSEL chip 1 and the photodiode 14 could be capable of transmitting and receiving at higher data rates, such as 25 Gbits/s, 40 Gbits/s, 80 Gbits/s, 100 Gbits/s.

The TIA 12 could also be combined with a limiting amplifier or a limiting amplifier could be added after the TIA to produce a more consistent output signal.

The VCSEL driver and TIA/LA could be CMOS, GaAs, Si—Ge or any other high speed semiconductor material based. The photodiode could be made of an appropriate semiconductor material with good responsivity at the VCSEL wavelength, such as Silicon (InGaAS, Ge etc. could be used depending on the wavelength). The VCSEL 1 wavelength could also be of various wavelengths such as 780 nm, 820 nm etc. In general any high speed VCSEL laser could be used.

The substrate thickness could vary from 50 um to several mm. Also, a composite substrate could be used including several transparent layers bonded together. Partial metalization, not blocking the VCSEL/photodiode optical line of sight could also be deposited between layers. The dielectric strength of the substrate should be high to provide high electrical isolation between inputs and outputs. The dielectric strength can be adjusted by properly selecting substrate material and thickness. For example, a 1 mm thick Pyrex substrate will have an electrical isolation (breakdown voltage) of about 14 kV.

Instead of a solid metal block, the heat sinks, 24 and 25 could be made of finned metal, or could be made of a ceramic material (e.g. aluminum nitride), or could be a thermally conductive foam or a thermally conductive epoxy resin that could also be used as a glob top. In general, any thermally conductive material that can be shaped to fill the gap between VCSEL, VCSEL driver, TIA and photodiode, and can keep the VCSEL temperature below a certain value (e.g. 50 C), could be used as a heat sink. Also, separate heat sinks could be used for the VCSEL 1, VCSEL driver 3, photodiode 14 and TIA 12.

The package 18 could be made of a ceramic, metallic, or plastic material. For example an injection molded plastic QFN package could be used to encapsulate the assembled substrate. The pin-out of the package could be leadless, ball grid array (BGA), flip chip, leaded, dual-in line (DIL) etc. In general numerous packaging variations exist to package an electronic device. Also, the leads 6 and 9 should have controlled impedance (e.g. 100 Ohm differential) to efficiently transfer high speed signals in and out of the package.

Also, wire-bonds could be replaced with ribbon bonds. Also, wirebonding or ribbon bonding could be done with ball bonds or wedge bonds.

Further, the impedance of the transmission lines 2, 4, 11, and 13 (e.g. less than 1 mm) could vary and could even be uncontrolled, if the traces are short.

Referring to FIG. 2. the method to make the optocoupler of this invention can include the following steps:
(i) Attach solder bumps on the VCSEL 1, VCSEL driver 3, photodiode 14 and TIA 12. This can be done with sputtering, evaporation, plating (electroplating or electroless), bonding (e.g. thermocompression bonding), stud bumping, stencil printing of solder paste etc. Solder bumps could be made of various solders (tin based, indium based etc) or metals (gold, indium etc.).
(ii) Form transmission lines 2, 4, 11, and 13, by depositing metal traces on substrate 17, and further deposit metal planes 15 and 16 on the substrate 17 by depositing metal or metal alloys (copper, aluminum, titanium, tungsten and their alloys etc.). Metal can be deposited by sputtering, evaporation, plating (electroplating or electroless), bonding (e.g. thermocompression bonding), solder paste deposition and reflowing etc.
(iii) Attach solder balls 5 and 10 to the substrate. This can be done with sputtering, evaporation, plating (electroplating or electroless), bonding (e.g. thermocompression bonding), stud bumping, stencil printing of solder paste and reflowing etc. Solder balls could be made of various solders (tin based, indium based, bismuth based, silver based etc) or metals (copper, aluminum, gold, indium etc.).
(iv) Attach VCSEL 1, VCSEL driver 3, photodiode 14 and TIA 12 to substrate 17. This can be done with a pick and place machine, such as a Carl-Seuss FC-250 and reflowing the solder bumps.
(v) Underfill VCSEL driver 3 and TIA 12 with an underfill material, such as Henkel Hysol underfill epoxies.
(vi) Underfill VCSEL 1 and photodiode 14 with an optically transparent underfill material, such as Henkel underfill epoxies.
(vii) Attach heat sink 24 to VCSEL 1, VCSEL driver 3. Thermal compound can be placed on the bottom of the package.
(viii) Attach heat sink 25 to the TIA 12 and photodiode 14.
(ix) Attach substrate 17 to un-lidded package 18 using a pick and place machine and reflow.
(x) Attach a lid to package 18 (e,g, by seam sealing, epoxy bonding soldering, brazing etc.)

I claim:

1. An optocoupler comprising a light emitting chip receiving electrical signals from a transmitting electronic circuit and a photodetector chip sending electrical signals to a receiving electronic circuit and an optically transparent substrate with at least two opposite flat sides and wherein the light emitting chip is attached to the first of the two opposite sides of the substrate with the light emitting surface of the light emitting chip facing the substrate and wherein the photodetector chip is attached to the second of the two opposite sides of the substrate with the light receiving surface of the photodetector chip facing the substrate and wherein the light emitting chip and photodetector chip are positioned in a manner that allows the light emitted by the light emitting chip to be received by the photodetector chip.

2. The optocoupler of claim 1 wherein said light emitting chip is a VCSEL laser chip.

3. The optocoupler of claim 1 wherein said transmitting electronic circuit is a VCSEL driver.

4. The optocoupler of claim 1 wherein said receiving electronic circuit is a transimpedance amplifier.

5. The optocoupler of claim 1 wherein said substrate is enclosed in an electronic package selected from the group consisting of leadless chip carrier (LCC), ball grid array (BGA), flip chip, dual-in line (DIL), quad flat no leads (QFN), pin grid array (PGA).

6. The optocoupler of claim 1 wherein said substrate further including metalized microvias through the substrate.

7. The optocoupler of claim 1 wherein said substrate further including metalized traces on at least one of said two opposite flat sides.

8. The optocoupler of claim 1 wherein said light emitting chip is attached to said substrate with solder bumps.

9. The optocoupler of claim 8 wherein the gap between the light emitting chip and the substrate is filled with underfill.

10. A method to make an optocoupler including the steps of:
(i) attaching solder bumps to a light emitting chip and a photodiode chip
(ii) depositing metal traces on a substrate
(iii) attaching the light emitting chip to the substrate
(iv) attaching the photodiode chip to the substrate
(v) underfilling the light emitting chip and photodiode chip with an optically transparent underfill material.

11. The method of claim 10 further including the steps of:
(i) attaching solder balls to the substrate
(ii) attaching the substrate to a package.

12. The method of claim 10 further including the steps of:
(i) attaching a heat sink to the light emitting chip
(ii) attaching a heat sink to the photodiode chip.
